(19) United States
(12) Patent Application Publication
(10) Pub. No.: US 2008/0178464 A1
(43) Pub. Date: Jul. 31, 2008

(54) METHOD FOR FABRICATING CIRCUIT BOARD

(75) Inventor: Chien-Hao Wang, Hsinchu County (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/780,707

(22) Filed: Jul. 20, 2007

(30) Foreign Application Priority Data
Jan. 26, 2007 (TW) 96103088

(51) Int. Cl. H05K 3/10; H05K 3/42; H01B 13/00

(52) U.S. Cl. 29/846; 29/852; 216/13

(57) ABSTRACT

A method for fabricating a circuit board comprises following steps. First, a metal substrate is provided and an electrophoretic deposition procedure is performed thereon to form an insulation film on a surface of the metal substrate. Next, a plurality of holes is formed on the insulation film to expose parts of the metal substrate. Then, a circuit layer is fabricated on the insulation film to cover the above-mentioned holes, so that the circuit layer is connected to the metal substrate through the holes. Further, a process of lithography and etching is conducted to fabricate the metal substrate into another circuit layer. Therefore, a circuit board with two circuit layers is completed.

### CROSS-REFERENCE TO RELATED APPLICATION

This application claims the priority benefit of Taiwan application serial no. 96103088, filed on Jan. 26, 2007. All disclosure of the Taiwan application is incorporated herein by reference.

### BACKGROUND OF THE INVENTION

1. Field of the Invention

The present invention generally relates to a method for fabricating a circuit board, and more particularly, to a method for fabricating a circuit board by using electrophoretic deposition procedure.

2. Description of Related Art

Along with the progress in science and technology and the improvement of life quality, consumers require an electronic product not only to have powerful functions, but also to be light, slim, short and small, which advances an electronic product to have higher integration degree and to be more capable.

To meet the above-mentioned tendency, a circuit board for disposing electronic components in an electronic product has been evolved from single circuit layer to multiple circuit layers such as 2-layers, 4-layers, 8-layers, even over 10-layers of traces, which enable more electronic components to be densely disposed on a circuit board to compact volume of electronic product.

In addition to usual epoxy resin substrate (for example, FR4, standing for Flame Resistant 4), a metal substrate is fabricated as a thinner circuit board with specific purpose. Referring to FIGS. 1A, 2A, 3A and 4, they are sectional diagrams of the circuit board for illustrating conventional fabricating process of circuit board employing a metal substrate. Referring to FIG. 1, first, a metal substrate 10 is provided. The metal substrate 10 can be made of copper.

Next, the metal substrate 10 is coated with an insulation material by using spin coating process, thus, an insulation layer 12 is formed. The above-mentioned insulation material herein can be polyimide. Referring to FIG. 1B, it is a schematic top view of FIG. 1A. FIG. 1B shows that the insulation layer 12 covers the metal substrate 10, while FIG. 1A is a sectional diagram of FIG. 1B along the a-a′ sectioning plane.

Referring to FIG. 2A, a plurality of holes 14 are formed on the above-mentioned insulation layer 12. Referring to FIG. 2B, it is a schematic top view of FIG. 2A. FIG. 2A is a sectional diagram of FIG. 2B along the b-b′ sectioning plane.

Referring to FIG. 3A, a metal layer is formed on the insulation layer 12 and the holes 14, following by conducting lithography, etching and the like to make the metal layer into a circuit layer 16. Referring to FIG. 3B, it is a schematic top view of FIG. 3A. FIG. 3A is a sectional diagram of FIG. 3B along the c-c′ sectioning plane.

The circuit layer 16 and the metal substrate 10 form interconnection structures via the holes 14. Note that the metal substrate 10 itself is a metal layer, therefore, lithography, etching process and the like can be conducted on the metal substrate 10 to create another circuit layer. In this way, the metal substrate 10 becomes a circuit board with two circuit layers shown in FIG. 4.

In the above-mentioned process, the insulation layer 12 is formed by using spin coating process. However, such a process likely makes the insulation layer 12 too thick and a poor flatness thereof.

Based on the above-described situation with the prior art, we search for a feasible solution of the above-mentioned problem as one of significant process of the field.

### SUMMARY OF THE INVENTION

Accordingly, the present invention is directed to effectively reduce thickness of circuit board and increase density of circuit layout by forming insulation films of the circuit board using electrophoretic deposition procedure.

The present invention is also directed to advance circuit characteristic of circuit board by forming insulation films of the circuit board using electrophoretic deposition procedure.

The present invention is also directed to form conductive holes during the same process with circuits, so that different circuit layers are laminated and electrically interconnected via the conductive holes to avoid the disadvantages of the prior art where via holes are formed after lamination process is finished, thereby resulting in a potential problem of poor alignment. Therefore, the present invention has higher manufacture yield.

As embodied and broadly described herein, the present invention provides a method for manufacturing a circuit board. The method includes following steps. First, a first metal substrate is provided, and the first metal substrate is conducted by an electrophoretic deposition procedure to form a first insulation film on a surface of the first metal substrate. Next, a plurality of first holes is formed on the first insulation film to expose parts of the first metal substrate. Finally, a first circuit layer is fabricated on the first insulation film and covers the above-mentioned first holes to make the first circuit layer electrically connected to the first metal substrate though the first holes.

The present invention provides a method for manufacturing a circuit board. The method includes following steps. First, a first metal substrate and a second metal substrate are provided for conducting an electrophoretic deposition procedure to form a first insulation film and a second insulation film respectively on each surface of the first and second metal substrates. Next, a plurality of first holes are formed on the first insulation film to expose parts of the first metal substrate; a plurality of second holes is formed on the second insulation film to expose parts of the second metal substrate.

Then, a first circuit layer is fabricated on the first insulation film and covers the first holes to make the first circuit layer electrically connected to the first metal substrate though the first holes; a second circuit layer is fabricated on the second insulation film and covers the second holes to make the second circuit layer electrically connected to the second metal substrate though the second holes.

Further, a first metal bump is formed on a surface of the first circuit layer and a second metal bump is formed on a surface of the second circuit layer. The first metal substrate is laminated onto the second metal substrate to constitute a compound substrate, wherein the second metal bump can be connected to the first metal bump to provide a channel electrically connected between the first and second metal substrate.

Finally, a third circuit layer and a fourth circuit layer are fabricated respectively on two opposite sides of the compound substrate, which are not covered by the first insulation film and the second insulation film respectively, and thereafter, two dielectric layers are formed respectively on the third circuit layer and the fourth circuit layer to complete the fabrication of the circuit board.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A, 2A, 3A and 4 are sectional diagrams of a circuit board for illustrating conventional fabricating process of the circuit board.

FIG. 1B is a schematic top view of FIG. 1A.

FIG. 2B is a schematic top view of FIG. 2A.

FIG. 3B is a schematic top view of FIG. 3A.

FIGS. 5A, 6A, 7A and 8-11 are sectional diagrams of a circuit board for illustrating fabricating process of the circuit board according to the first embodiment of the present invention.

FIG. 5B is a schematic top view of FIG. 5A.

FIG. 6B is a schematic top view of FIG. 6A.

FIG. 7B is a schematic top view of FIG. 7A.

FIGS. 12-14 are sectional diagrams of a circuit board for illustrating fabricating process of the circuit board according to the second embodiment of the present invention.

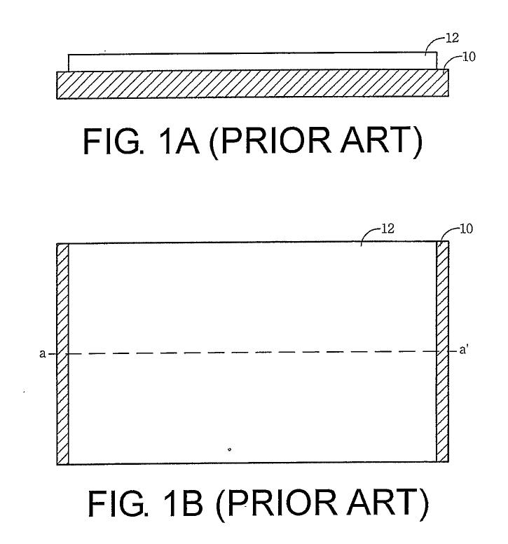

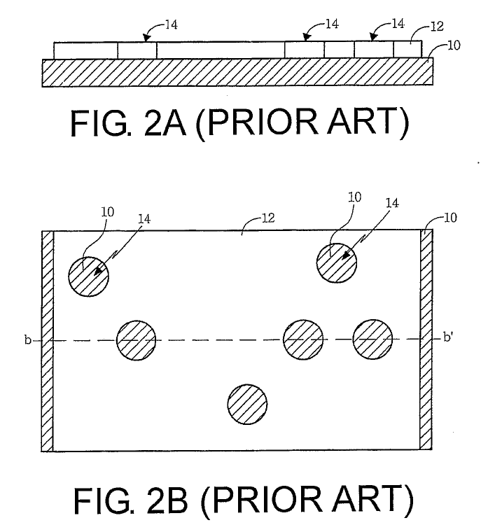

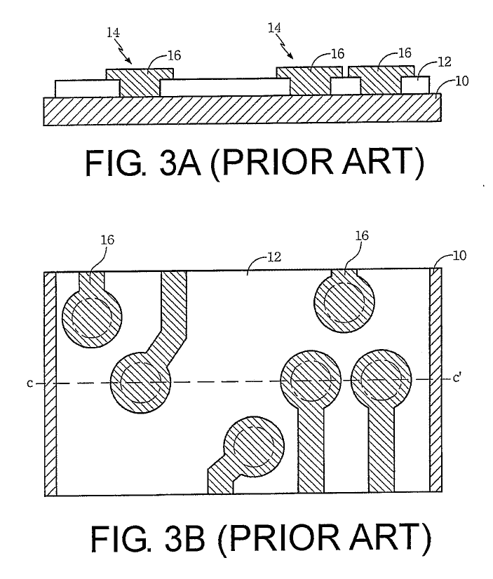

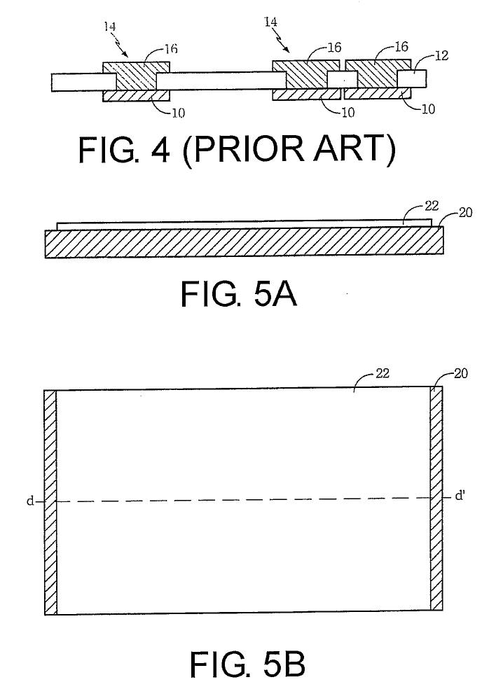

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIGS. 5A, 6A, 7A and 8-11 are sectional diagrams of a circuit board for illustrating fabricating process of the circuit board according to the first embodiment of the present invention. Referring to FIG. 5A, first, a first metal substrate 20 is provided for conducting an electrophoretic deposition procedure to form a first insulation film 22 on a surface of the first metal substrate 20. Referring to FIG. 5B, it is a schematic top view of FIG. 5A showing the first insulation film 22 covers the first metal substrate 20, while FIG. 5A is a sectional drawing of FIG. 5B along the d-d′ sectioning plane.

The material of the first metal substrate 20 can be copper or aluminum. The above-mentioned electrophoretic deposition procedure further includes: depositing polymeric micelles on a surface of the first metal substrate 20, and conducting a thermal treatment procedure to polymerize the polymeric micelles into the first insulation film 22.

The polymeric micelles are fine dispersed in solution, and then an electric field is used to electrophorese the polymeric micelles to be deposed on the surface of the first metal substrate 20. Since the micelles in a solution are unpolymerized macromolecules in glue state; thus, a thermal treatment procedure including dehydration and cyclization processes is essentially conducted to polymerize the polymeric micelles into the required polymeric structure.

The polymeric micelles include inorganic silica oxide particles and polymer precursors, wherein the polymer precursor is selected from one of polyimide resin and ramification thereof, epoxy and the ramification thereof, halogen-containing polymer resin, flame resistant polymer resin containing phosphor, silicon and sulfur or a combination thereof.

The electrophoretic deposition procedure is able to control the thickness of insulation films by setting the current, the voltage or the time of depositing, and the thickness can be less than 10 microns by the control. Besides, the deposited film layer of the insulation film is quite even and flat. Therefore, the present invention can provide an insulation film much thinner and more flat than the conventional insulation layer.

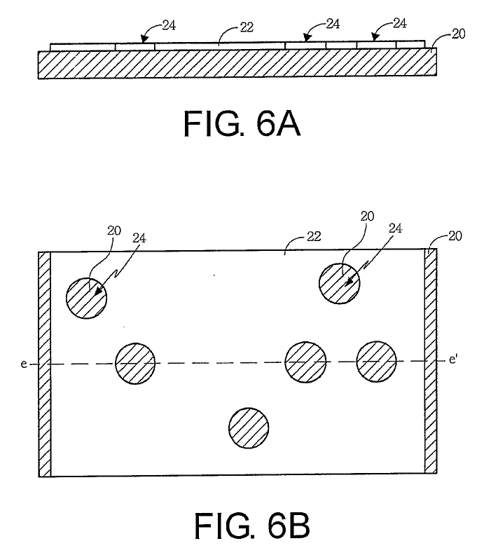

Next, referring to FIG. 6A, after forming the first insulation film 22 on the first metal substrate 20, a plurality of first holes 24 are formed on the first insulation film 22 to expose parts of the first metal substrate 20. Referring to FIG. 6B, it is a schematic top view of FIG. 6A showing a plurality of first holes 24 is formed on the first insulation film 22, while FIG. 6A is a sectional drawing of FIG. 6B along the e-e′ sectioning plane, wherein the above-mentioned first holes 24 are formed by laser drilling. However, when the first insulation film 22 is made of photosensitive material, the first holes 24 can be formed by exposing and developing process or by etching process.

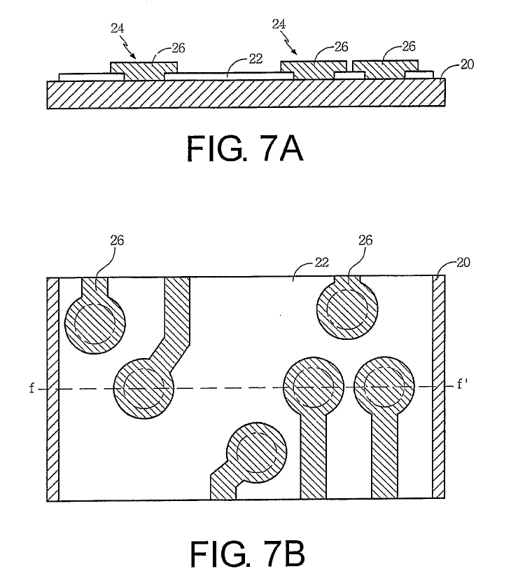

Referring to FIG. 7A, after forming the first holes 24, a first circuit layer 26 is fabricated on the first insulation film 22, and the first circuit layer 26 covers the above-mentioned first holes 24, so that the first circuit layer 26 is connected to the first metal substrate 20 through the first holes 24 to provide interconnection therein. Referring to FIG. 7B, it is a schematic top view of FIG. 7A showing the wiring of the first circuit layer 26, while FIG. 7A is a sectional drawing of FIG. 7B along the f-f′ sectioning plane.

The method for fabricating the first circuit layer 26 includes following steps. First, a metal layer is formed to cover the first insulation film 22 and the first holes 24. Next, a patterned photoresist layer is formed on the above-mentioned metal layer for conducting etching process to pattern the metal layer and the first circuit layer 26 is completed accordingly. Finally, the patterned photoresist layer is removed. In a preferred embodiment, the patterned photoresist layer is a dry film.

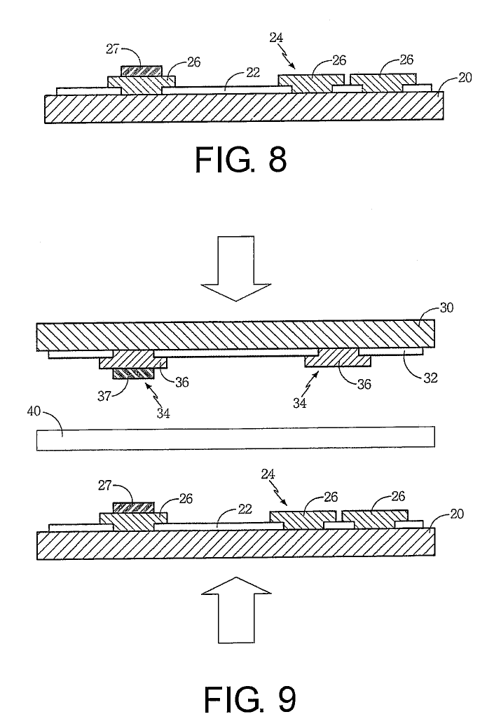

Referring to FIG. 8, after fabricating the first circuit layer 26, a first metal bump 27 is formed on a surface of the first circuit layer 26, wherein the first metal bump 27 can be formed by plating.

Referring to FIG. 9, a second metal substrate 30 is provided and a process same as that for the above-mentioned first metal substrate 20 is conducted. The process includes: conducting an electrophoretic deposition procedure to form a second insulation film 32 on a surface of the second metal substrate 30 and forming a plurality of second holes 34 on the second insulation film 32 to expose parts of the second metal substrate 30.

After forming the second holes 34, a second circuit layer 36 is fabricated on the second insulation film 32, and the second circuit layer 36 covers the second holes 34, so that the second circuit layer 36 is connected to the second metal substrate 30 through the second holes 34 to provide interconnection therein. Further, a second metal bump 37 is formed on a surface of the second circuit layer 36.

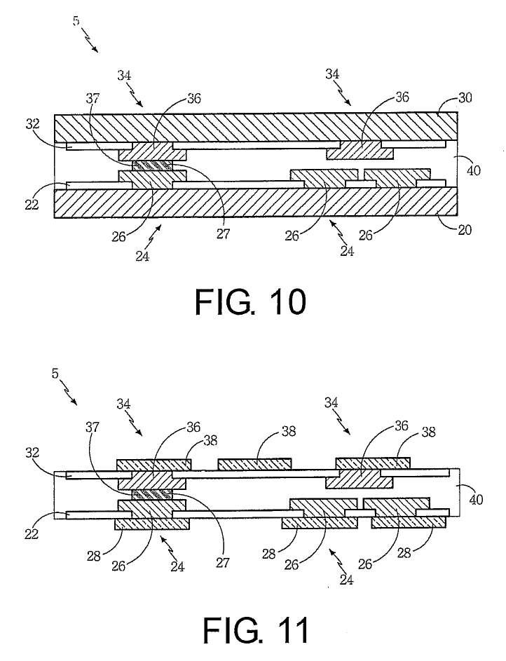

Referring to FIG. 9, the first metal substrate 20 covers onto the second metal substrate 30 and both are laminated together to constitute a compound substrate 5 showed in FIG. 10, wherein the first metal substrate 20 and the second metal substrate 30 are respectively laminated on two sides of an dielectric layer 40.

When the two metal substrates are laminated together, second metal bump 37 is joined with the first metal bump 27 to provide a channel electrically connected between the first circuit layer 26 and the second circuit layer 36 shown in FIG. 10. At the point, the joint of the two metal bumps functions like a conductive hole to serve as a conductive channel between the circuit layers.

Referring to FIG. 11, since both sides, which the first insulation film 22 and the second insulation film 32 do not cover, of the compound substrate 5 are metal layers, the compound substrate 5 is available for fabricating a third circuit layer 28 and a fourth circuit layer 38 on respective side thereof. That is, the original two metal substrates are used to form the outmost circuit layers.

The process for fabricating the third circuit layer 28 and the fourth circuit layer 38 are as follows. First, two patterned photoresist layers are formed respectively on the two metal layers, where the first insulation film 22 and the second insulation film 32 do not cover, of the compound substrate 5. Next, parts of the above-mentioned metal layers are etched and the two patterned photoresist layers are removed later to complete the fabrication of two outmost circuit layers.

Note that the metal substrates provided by the process are usually designed with an appropriate thickness to make the metal substrates sufficiently rigid, so that the metal substrates are not too flexible to cause a warpage problem due to insufficient support rigid in process.

Prior to fabricating the third circuit layer 28 and the fourth circuit layer 38, a thinning processing is conducted on the metal substrates. The so-called thinning processing makes the metal layers at both sides of the compound substrate 5 thinner by using mechanical lapping or chemical etching.

After completing the third circuit layer 28 and the fourth circuit layer 38, two solder masks are formed respectively on the surfaces of the two circuit layers for protecting the wirings.

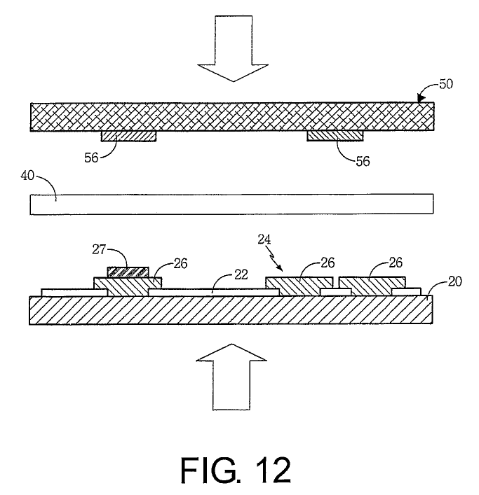

FIGS. 12-14 are diagrams of the method for fabricating a circuit board according to the second embodiment of the present invention. Referring to FIG. 12, after forming the first metal bump 27 on a surface of the first circuit layer 26, another circuit substrate 50 is provided, on which a second circuit layer 56 is formed. The substrate material of the circuit substrate 50 is metal or other usual insulation material, and the circuit substrate 50 can be a circuit board with multiple circuit layers.

Continuing to FIG. 12, the first metal substrate 20 covers the circuit substrate 50 and both are laminated together to constitute a compound substrate 6, wherein the first metal substrate 20 and the circuit substrate 50 are laminated at both sides of a dielectric layer 40.

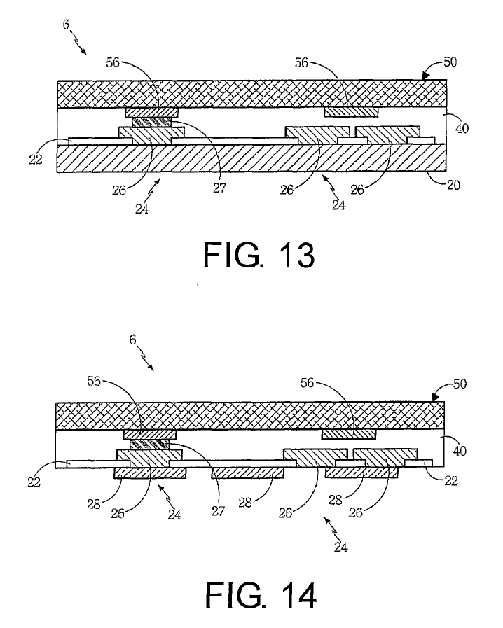

The first metal bump 27 in the compound substrate 6 formed by laminating two substrates serves as a channel electrically connected between the first circuit layer 26 of the first metal substrate 20 and the second circuit layer 56 of the circuit substrate 50, as shown in FIG. 13, and at the point the first metal bump 27 functions as a conductive hole.

Referring to FIG. 14, since a surface of the compound substrate 6, where the first insulation film 22 does not cover, is a metal layer, a third circuit layer 28 can be formed on one side of the compound substrate 6 where the first insulation film 22 does not cover.

The process for fabricating the third circuit layer 28 is as follows. First, a patterned photoresist layer is formed on the metal layer, where the first insulation film 22 does not cover, of the compound substrate 6. Next, parts of the above-mentioned metal layers are etched and the patterned photoresist layer is removed later to complete the fabrication of the third circuit layer 28.

Prior to fabricating the third circuit layer 28, a thinning processing is conducted on the metal layer of the first metal substrate 20 so as to make the thickness of the metal layer suitable for the fabrication of a circuit layer. After completing the third circuit layer 28, a solder mask is formed on the surface thereof for protecting the wirings.

In summary, the method for fabricating a circuit board of the present invention has following advantages:

1. Since the insulation films of the circuit board are formed by using an electrophoretic deposition procedure, the insulation films are thinner, which is able to effectively reduce the thickness of the circuit board and to advance the density of the circuit layout.

2. Since the insulation films formed by using an electrophoretic deposition procedure are more even, the circuit layers formed on the insulation films have better circuit characteristics.

3. Since conductive holes are formed simultaneously with circuits, thus, the different circuit layers are laminated to conduct with each other, which is able to avoid the disadvantages of the prior art where conductive holes are formed after laminating process is finished, thereby resulting in a potential problem of poor alignment. Therefore, the present invention has higher manufacture yield.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a circuit board, comprising:
providing a first metal substrate;
conducting an electrophoretic deposition procedure to form a first insulation film on a surface of the first metal substrate;
forming a plurality of first holes on the first insulation film to expose parts of the first metal substrate;
fabricating a first circuit layer on the first insulation film and covering the first holes to make the first circuit layer connected to the first metal substrate through the first holes;
forming a first metal bump on a surface of the first circuit layer;
providing a circuit substrate, which has a second circuit layer on a surface of the circuit substrate; and
laminating the first metal substrate and the circuit substrate to constitute a compound substrate, wherein the first circuit layer of the first metal substrate is electrically connected to the second circuit layer of the circuit substrate through the first metal bump.

2. The method for fabricating a circuit board according to claim 1, wherein the step of conducting the electrophoretic deposition procedure further comprises following steps:
depositing polymeric micelles on the surface of the first metal substrate; and
conducting a thermal treatment procedure to polymerize the polymeric micelles into the first insulation film.

3. The method for fabricating a circuit board according to claim 2, wherein the thermal treatment procedure comprises at least dehydration and cyclization processes.

4. The method for fabricating a circuit board according to claim 1, wherein the method for fabricating the first circuit layer comprises following steps:
forming a metal layer to cover the first insulation film and the first holes;
forming a patterned photoresist layer on the metal layer;
conducting etching to pattern the metal layer into the first circuit layer; and
removing the patterned photoresist layer.

5. The method for fabricating a circuit board according to claim 1, wherein the first metal bump is formed on the first circuit layer by plating.

6. The method for fabricating a circuit board according to claim 1, further comprising a thinning processing after laminating the first metal substrate and the circuit substrate.

7. The method for fabricating a circuit board according to claim 1, further comprising forming a third circuit layer on a surface of the first metal substrate of the compound substrate, where the first insulation film does not cover, after laminating the first metal substrate and the circuit substrate.

8. The method for fabricating a circuit board according to claim 7, wherein the step of fabricating the third circuit layer comprises following steps:
forming a patterned photoresist layer on the surface of the first metal substrate of the compound substrate, where the first insulation film does not cover;
etching parts of the first metal substrate; and
removing the patterned photoresist layer.

9. The method for fabricating a circuit board according to claim 7, wherein the step of fabricating the third circuit layer on the compound substrate further comprises forming a solder mask on the third circuit layer.

10. A method for fabricating a circuit board, comprising:
providing a first metal substrate and a second metal substrate;
conducting an electrophoretic deposition procedure to form a first insulation film on a surface of the first metal substrate and a second insulation film on a surface of the second metal substrate;
forming a plurality of first holes on the first insulation film to expose parts of the first metal substrate and forming a plurality of second holes on the second insulation film to expose parts of the second metal substrate;
fabricating a first circuit layer on the first insulation film and covering the first holes to make the first circuit layer connected to the first metal substrate through the first holes, and fabricating a second circuit layer on the second insulation film and covering the second holes to make the second circuit layer connected to the second metal substrate through the second holes;
forming a first metal bump on a surface of the first circuit layer and forming a second metal bump on a surface of the second circuit layer;
laminating the first metal substrate and the second metal substrate to constitute a compound substrate, wherein the second metal bump joins with the first metal bump to provide a channel electrically connected between the first circuit layer and the second circuit;
fabricating a third circuit layer and a fourth circuit layer respectively on two opposite sides, which are not covered by the first insulation film and the second insulation film, of the compound substrate; and
forming a solder mask on the third circuit layer and forming a solder mask on the fourth circuit layer.

11. The method for fabricating a circuit board according to claim 10, wherein the step of conducting the electrophoretic deposition procedure further comprises following steps:
depositing polymeric micelles on the surface of the first metal substrate and the surface of the second metal substrate; and
conducting a thermal treatment procedure to polymerize the polymeric micelles into the first insulation film and the second insulation film.

12. The method for fabricating a circuit board according to claim 11, wherein the thermal treatment procedure comprises at least dehydration and cyclization processes.

13. The method for fabricating a circuit board according to claim 10, wherein the first metal bump and the second metal bump are formed by plating respectively on the first circuit layer and the second circuit layer.

14. The method for fabricating a circuit board according to claim 10, wherein after the step of laminating the first metal substrate and the second metal substrate further comprises a thinning processing.

15. The method for fabricating a circuit board according to claim 10, wherein the step of fabricating the third circuit layer and the fourth circuit layer on two opposite sides of the compound substrate comprises following steps:
respectively forming a patterned photoresist layer on both sides of the compound substrate, where the first insulation film and the second insulation film do not cover;
etching parts of the first metal substrate and the second metal substrate; and
removing the patterned photoresist layers.
